(19) United States
(12) Patent Application Publication
(10) Pub. No.: US 2026/0206385 A1
(43) Pub. Date: Jul. 16, 2026

(54) DISPLAY DEVICE AND METHOD OF MANUFACTURING THE SAME

(71) Applicant: LG Display Co., Ltd., Seoul (KR)

(72) Inventors: Su-Min LEE, Paju-si (KR); Yang-Hwan KIM, Paju-si (KR); Tae-Yong KIM, Paju-si (KR); Young-In JANG, Paju-si (KR)

(73) Assignee: LG Display Co., Ltd., Seoul (KR)

(21) Appl. No.: 19/338,928

(22) Filed: Sep. 24, 2025

(30) Foreign Application Priority Data
Nov. 22, 2024 (KR) 10-2024-0168019

(51) Int. Cl. H10H 29/39

(52) U.S. Cl. CPC H10H 29/39

(57) ABSTRACT

A display device can include a substrate including a first pixel region and a second pixel region, a planarization layer disposed on the substrate, the planarization layer including a recessed portion in each of the first pixel region and the second pixel region, a first electrode disposed in each of the first pixel region and the second pixel region, the first electrode overlapping with the recessed portion, and a second electrode disposed in each of the first pixel region and the second pixel region, the second electrode overlapping with the first electrode. Also, the display device can further include a light-emitting element disposed in the first pixel region, the light-emitting element being electrically connected to the first electrode and the second electrode of the first pixel region, in which no light-emitting element is included in the second pixel region.

### CROSS-REFERENCE TO RELATED APPLICATION

The present application claims priority to Korean Patent Application No. 10-2024-0168019 filed in the Republic of Korea on Nov. 22, 2024, the entire contents of which are hereby expressly incorporated by reference into the present application.

### BACKGROUND

### Technical Field

The present disclosure relates to a display device, and more particularly, for example, without limitation, to a display device including a light-emitting diode and a method of manufacturing the same.

### Discussion of the Related Art

As the information society progresses, the demand for different types of display devices continues increase, and flat panel display devices (FPD) such as liquid crystal display devices and light-emitting diode display devices have been developed and applied to various fields.

Among the flat panel display devices, light-emitting diode display devices emit light due to the radiative recombination of an exciton. The exciton is formed from an electron and a hole by injecting charges into a light-emitting layer between a cathode for injecting electrons and an anode for injecting holes in a light-emitting diode.

The light-emitting diode display device can offer various advantages and improved properties. For instance, compared to the liquid crystal display device, because it is self-luminous, the light-emitting diode display device has a wide viewing angle, and since a backlight unit is not required, the light-emitting diode display device has an ultra-thin thickness and light weight. In addition, the light-emitting diode display device is also advantageous in power consumption.

The light-emitting diode display device can include inorganic-based light-emitting elements and organic-based light-emitting elements. The inorganic-based light-emitting elements have relatively excellent stability, fast response characteristics, and high contrast ratios, and micro light-emitting diodes (micro LEDs or uLED) are widely used as the inorganic-based light-emitting elements for high resolution.

The inorganic-based light-emitting elements are formed on a separate growth substrate and are transferred to a panel of a display device. However, since a pixel pitch varies depending on the resolution or size, it is necessary to individually manufacture panels corresponding to respective pixel pitches.

For example, existing display manufacturing processes and display designs are often rigid and inefficient, requiring completely different production lines for each unique configuration, which can include different combinations of screen sizes and resolutions. This lack of adaptability creates significant manufacturing hurdles, and slows down the introduction of new and varied display products to the market.

Thus, a need exists for a more flexible and streamlined approach to display fabrication and design configuration that can accommodate diverse product specifications without requiring fundamental changes to the manufacturing process.

Further, a need exists for a display device capable of responding to different resolutions and/or sizes with the same type of base panel configuration and a method of manufacturing the same.

### SUMMARY OF THE DISCLOSURE

Accordingly, embodiments of the present disclosure are directed to a display device that substantially obviates one or more of the problems due to limitations and disadvantages of the related art.

An aspect of the present disclosure is to provide a display device capable of responding to different resolutions and/or sizes with one panel and a method of manufacturing the same.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, a display device includes a substrate on which a first pixel region and a second pixel region are defined, a planarization layer provided over the substrate and having a recessed portion in each of the first and second pixel regions, a first electrode provided in each of the first and second pixel regions and disposed over the recessed portion, a second electrode provided in each of the first and second pixel regions and disposed over the first electrode, and a light-emitting element provided in the first pixel region and electrically connected to the first electrode and the second electrode of the first pixel region, in which no light-emitting element is provided in the second pixel region.

In another aspect of the present disclosure, a display device includes a substrate on which a first pixel region and a second pixel region are defined, a planarization layer provided over the substrate and having a recessed portion in each of the first and second pixel regions, a first electrode provided in each of the first and second pixel regions and disposed over the recessed portion, a second electrode provided in each of the first and second pixel regions and disposed over the first electrode, and a light-emitting element provided in the first pixel region and electrically connected to the first electrode and the second electrode of the first pixel region, in which the first electrode of the first pixel region has an opening, and the first electrode of the second pixel region does not have an opening.

In another aspect of the present disclosure, a method of manufacturing a display device includes steps of preparing a substrate on which a first pixel region and a second pixel region are defined, forming a planarization layer over the substrate, the planarization layer having a recessed portion in each of the first and second pixel regions, forming an adhesive layer in the recessed portion of the first pixel region, transferring a light-emitting element on the adhesive layer of the first pixel region, forming a first electrode over the recessed portion in each of the first and second pixel regions, the first electrode electrically connected to the light-emitting element, and forming a second electrode over the first electrode in each of the first and second pixel regions, the second electrode electrically connected to the light-emitting element, in which no light-emitting element is provided in the second pixel region.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are explanatory examples and are intended to provide further explanation of the inventive concepts as claimed.

### BRIEF DESCRIPTION OF THE DRAWINGS

The accompanying drawings, which are included to provide a further understanding of the disclosure and which are incorporated in and constitute a part of this application, illustrate embodiments of the disclosure and together with the description serve to explain various principles of the disclosure. In the drawings:

FIG. 1 is a view schematically showing a display device according to an embodiment of the present disclosure;

FIG. 2 is a schematic cross-sectional view of a display panel of a display device according to an embodiment of the present disclosure;

FIG. 3 is a schematic view showing a part of a first display device according to an embodiment of the present disclosure;

FIG. 4 is a schematic view showing a part of a second display device according to an embodiment of the present disclosure;

FIG. 5 is a schematic cross-sectional view of a display panel of a display device according to another embodiment of the present disclosure;

FIG. 6 is a schematic plan view of a first pixel region of a display panel of a display device according to an embodiment of the present disclosure;

FIG. 7 is a schematic plan view of a second pixel region of a display panel of a display device according to an embodiment of the present disclosure;

FIGS. 8A to 8H are schematic cross-sectional views of a display panel of a display device in steps of manufacturing the same according to an embodiment of the present disclosure;

FIG. 9 is a schematic cross-sectional view of a display panel of a display device according to another embodiment of the present disclosure;

FIG. 10 is a schematic cross-sectional view of a display panel of a display device according to yet another embodiment of the present disclosure; and

FIGS. 11A to 11I are schematic cross-sectional views of a display panel of a display device in steps of manufacturing the same according to an embodiment of the present disclosure.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted or can be briefly discussed. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations can be selected only for convenience of writing the specification and can be thus different from those used in actual products.

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

Any implementation described herein as an “example” is not necessarily to be construed as preferred or advantageous over other implementations.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure.

Further, in the following description of the present disclosure, when a detailed description of a known related art is determined to unnecessarily obscure the gist of the present disclosure, the detailed description thereof will be omitted herein or can be briefly discussed.

When terms such as “including,” “having,” “comprising” and the like mentioned in this disclosure are used, other parts can be added unless the term “only” is used herein.

Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, situations that are not continuous or sequential can also be included.

As used herein, the terms such as “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner. For example, the term “in contact with,” as used herein, encompasses both “indirect contact” and “direct contact.” Accordingly, when the phrase “A is in contact with B” is used, it implies that other components can be present between A and B, unless explicitly specified as “A is in direct contact with B.”

Although the terms such as first, second, and the like are used to describe various components, these components are not substantially limited by these terms. These terms are used only to distinguish one component from another component, and may not define any order or sequence. Therefore, a first component described below can substantially be a second component within the technical idea of the present disclosure.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Rather, these embodiments can be provided so that this disclosure can be sufficiently thorough and complete to assist those skilled in the art to fully understand the scope of the present disclosure. Furthermore, the present disclosure is only defined by scopes of claims.

Features of various embodiments of the present disclosure can be partially or entirely united or combined with each other, technically various interlocking and driving are possible, and each of the embodiments can be independently implemented with respect to each other or implemented together in a related relationship. Also, the term “can” used herein includes all meanings and definitions of the term “may.”

Hereinafter, example embodiments of the present disclosure will be described in detail with reference to accompanying drawings. All the components of each display device/apparatus according to all embodiments of the present disclosure are operatively coupled and configured.

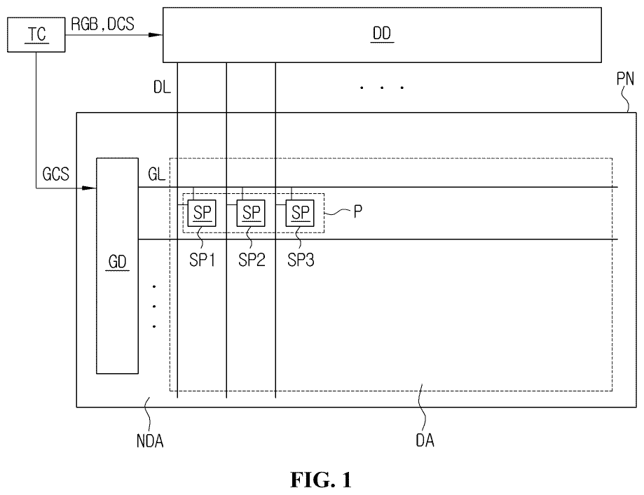

FIG. 1 is a view schematically showing a display device according to an embodiment of the present disclosure. The display device can be a micro LED (light-emitting diode) display device or a mini LED display device. However, embodiments of the present disclosure are not limited thereto, and in other embodiments, for example, the display device can be an organic light-emitting diode (OLED) display device.

In FIG. 1, the display device according to an embodiment of the present disclosure can include a display panel PN, a timing controller TC, a data driver DD, and a gate driver GD.

The timing controller TC can generate image data RGB, a data control signal DCS, and a gate control signal GCS using an image signal and a plurality of timing signals, such as a data enable signal, a horizontal synchronization signal, a vertical synchronization signal, and a clock, transmitted from an external system such as a graphic card or a TV system.

In addition, the timing controller TC can transmit the generated image data RGB and the generated data control signal DCS to the data driver DD and can transmit the generated gate control signal GCS to the gate driver GD.

The data driver DD can generate a data voltage, which is a data signal, using the image data RGB and the data control signal DCS transmitted from the timing controller TC and can apply the generated data voltage to a data line DL of the display panel PN.

The gate driver GD can generate a gate voltage, which is a gate signal, using the gate control signal GCS transmitted from the timing controller TC and can apply the generated gate voltage to a gate line GL of the display panel PN.

Here, the gate driver GD can be provided as a gate-in-panel (GIP) type formed together on a substrate of the display panel PN on which the gate line GL, the data line DL, and sub-pixels SP are formed and can be disposed in a non-display area NDA.

In the embodiment of FIG. 1, the gate driver GD can be disposed on one side of the display panel PN, but in other embodiments, two gate drivers can be disposed on both sides of the display panel PN, respectively.

The display panel PN can include a display area DA displaying an image and a non-display area NDA surrounding the display area DA. The display panel PN can display the image using the gate voltage supplied from the gate driver GD and the data voltage supplied from the data driver DD. To do this, the display panel PN can include a plurality of pixel P, a plurality of gate lines GL, and a plurality of data lines DL disposed in the display area DA.

Each of the plurality of pixels P can include a plurality of sub-pixels SP and gate lines GL and the data lines DL can cross each other to define each pixel P and/or the sub-pixels SP. For example, each of the plurality of pixels P can include first, second, and third sub-pixels SP1, SP2, and SP3, and the first, second, and third sub-pixels SP1, SP2, and SP3 can be red, green, and blue sub-pixels, respectively.

At least one light-emitting diode, a plurality of thin film transistors, and at least one storage capacitor can be provided in each sub-pixel SP.

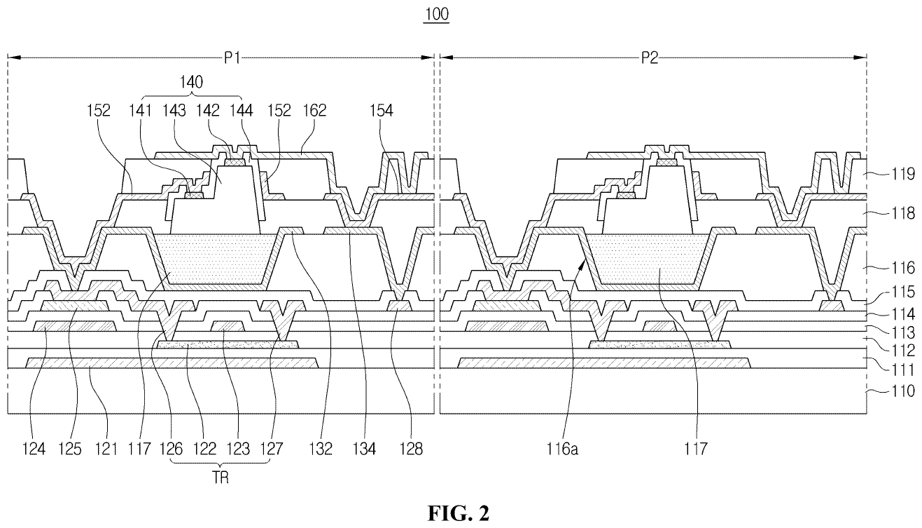

The cross-sectional configuration of the display device according to the embodiment of the present disclosure will be described with reference to FIG. 2.

FIG. 2 is a schematic cross-sectional view of a display panel of a display device according to a first embodiment of the present disclosure and shows regions corresponding sub-pixels of two pixels adjacent to each other.

In FIG. 2, a display panel 100 of a display device according to the first embodiment of the present disclosure can include a substrate 110 provided with a first pixel region P1 and a second pixel region P2. The first pixel region P1 and the second pixel region P2 can have the same configuration.

For example, a thin film transistor TR and a light-emitting element 140 can be provided in each of the first pixel region P1 and the second pixel region P2 over the substrate 110. The light-emitting element 140 can be connected to the thin film transistor TR and a power line 128. In other words, according to an embodiment, all the pixels regions can include light-emitting elements in order to provide a display panel that has a high resolution, but embodiments are not limited thereto.

Specifically, the first pixel region P1 and the second pixel region P2 can be provided over the substrate 110. The first pixel region P1 and the second pixel region P2 can correspond to first and second pixels adjacent to each other, respectively.

The substrate 110 can be a glass substrate or a plastic substrate. For example, polyimide can be used for the plastic substrate, and the plastic substrate can have a stacked structure including at least one polyimide layer and at least one inorganic layer. However, embodiments of the present disclosure are not limited thereto.

A light-shielding layer 121 can be provided in each of the first and second pixel regions P1 and P2 on the substrate 110. The light-shielding layer 121 can be formed of a conductive material such as metal. For example, the light-shielding layer 121 can be formed of one or more of: aluminum (Al), copper (Cu), molybdenum (Mo), titanium (Ti), chromium (Cr), nickel (Ni), tungsten (W), and an alloy thereof. The light-shielding layer 121 can have a single-layered structure or a multiple-layered structure.

A buffer layer 111 can be provided on the light-shielding layer 121. The buffer layer 111 can be disposed substantially all over the substrate 110. The buffer layer 111 can be formed as a single layer or multiple layers of an inorganic insulating material. For example, the inorganic insulating material of the buffer layer 111 can include silicon nitride (SiNx), silicon oxide (SiOx), or silicon oxynitride (SiON).

An active layer 122 can be provided on the buffer layer 111 in each of the first and second pixel regions P1 and P2. The active layer 122 can overlap with the light-shielding layer 121, and the light-shielding layer 121 can block light incident on the active layer 122 and prevent or reduce the active layer 122 from deteriorating due to the light.

The active layer 122 can include a channel region at its central part and source and drain regions at both sides of the channel region. The active layer 122 can be formed of an oxide semiconductor material. Alternatively, the active layer 122 can be formed of polycrystalline silicon, and in this situation, both ends of the active layer 122 can be doped with impurities.

A gate insulation layer 112 can be provided on the active layer 122 and the buffer layer 111. The gate insulation layer 112 can be disposed substantially all over the substrate 110. The gate insulation layer 112 can be formed as a single layer or multiple layers of an inorganic insulating material. For example, the inorganic insulating material of the gate insulation layer 112 can include silicon nitride (SiNx), silicon oxide (SiOx), or silicon oxynitride (SiON).

A gate electrode 123 and a first capacitor electrode 124 can be formed on the gate insulation layer 112 in each of the first and second pixel regions P1 and P2. The gate electrode 123 can overlap with the active layer 122 and can be disposed to correspond to the central part of the active layer 122. Accordingly, the gate electrode 123 can also overlap with the light-shielding layer 121.

The first capacitor electrode 124 can be spaced apart from the active layer 122 and can overlap with the light-shielding layer 121.

The gate electrode 123 and the first capacitor electrode 124 can be formed of a conductive material such as metal. For example, the gate electrode 123 and the first capacitor electrode 124 can be formed of one or more of: aluminum (Al), copper (Cu), molybdenum (Mo), titanium (Ti), chromium (Cr), nickel (Ni), tungsten (W), and an alloy thereof. The gate electrode 123 and the first capacitor electrode 124 can have a single-layered structure or a multiple-layered structure.

A first interlayer insulation layer 113 can be provided on the gate electrode 123 and the first capacitor electrode 124. The first interlayer insulation layer 113 can be disposed substantially all over the substrate 110. The first interlayer insulation layer 113 can be formed as a single layer or multiple layers of an inorganic insulating material. For example, the inorganic insulating material of the first interlayer insulation layer 113 can include silicon nitride (SiNx), silicon oxide (SiOx), or silicon oxynitride (SiON).

A second capacitor electrode 125 can be provided on the first interlayer insulation layer 113 in each of the first and second pixel regions P1 and P2. The second capacitor electrode 125 can overlap with the first capacitor electrode 124 to thereby form a storage capacitor with the first interlayer insulation layer 113 interposed therebetween as a dielectric. The second capacitor electrode 125 can also overlap with the light-shielding layer 121.

The second capacitor electrode 125 can be formed of a conductive material such as metal. For example, the second capacitor electrode 125 can be formed of one or more of: aluminum (Al), copper (Cu), molybdenum (Mo), titanium (Ti), chromium (Cr), nickel (Ni), tungsten (W), and an alloy thereof. The second capacitor electrode 125 can have a single-layered structure or a multiple-layered structure.

A second interlayer insulation layer 114 can be provided on the second capacitor electrode 125. The second interlayer insulation layer 114 can be disposed substantially all over the substrate 110. The second interlayer insulation layer 114 can be formed as a single layer or multiple layers of an inorganic insulating material. For example, the inorganic insulating material of the second interlayer insulation layer 114 can include silicon nitride (SiNx), silicon oxide (SiOx), or silicon oxynitride (SiON).

A source electrode 126, a drain electrode 127, and a power line 128 can be provided on the second interlayer insulation layer 114 in each of the first and second pixel regions P1 and P2.

The source electrode 126 and the drain electrode 127 can be spaced apart from each other with the gate electrode 123 positioned therebetween and can be in contact with both ends of the active layer 122 through contact holes provided in the first and second interlayer insulation layers 113 and 114 and the gate insulation layer 112.

In addition, the source electrode 126 can extend to overlap with the first and second capacitor electrodes 124 and 125. The source electrode 126 can be in contact with the second capacitor electrode 125 through a contact hole provided in the second interlayer insulation layer 114.

The active layer 122, the gate electrode 123, the source electrode 126, and the drain electrode 127 can constitute a thin film transistor TR. The thin film transistor TR can be a driving transistor. However, embodiments of the present disclosure are not limited thereto.

Meanwhile, the power line 128 can be spaced apart from the thin film transistor TR and the light-shielding layer 121. The power line 128 can transmit a high potential voltage VDD. The power line 128 can be disposed between adjacent pixel regions.

The source electrode 126, the drain electrode 127, and the power line 128 can be formed of a conductive material such as metal. For example, the source electrode 126, the drain electrode 127, and the power line 128 can be formed of one or more of: aluminum (Al), copper (Cu), molybdenum (Mo), titanium (Ti), chromium (Cr), nickel (Ni), tungsten (W), and an alloy thereof. The source electrode 126, the drain electrode 127, and the power line 128 can have a single-layered structure or a multiple-layered structure.

A passivation layer 115 can be provided on the source electrode 126, the drain electrode 127, and the power line 128. The passivation layer 115 can be disposed substantially all over the substrate 110. The passivation layer 115 can be formed as a single layer or multiple layers of an inorganic insulating material. For example, the inorganic insulating material of the passivation layer 115 can include silicon nitride (SiNx), silicon oxide (SiOx), or silicon oxynitride (SiON).

A first planarization layer 116 can be provided on the passivation layer 115. The first planarization layer 116 can be disposed substantially all over the substrate 110.

The first planarization layer 116 can eliminate a step difference due to the layers thereunder and can have a substantially flat top surface. The first planarization layer 116 can be formed of an organic insulating material such as photosensitive acrylic polymer (photo acryl).

The first planarization layer 116 can have a recessed portion 116a corresponding to the light-emitting element 140 in each of the first and second pixel regions P1 and P2. The recessed portion 116a can be disposed over the thin film transistor TR. However, embodiments of the present disclosure are not limited thereto, and in other embodiments, the recessed portion 116a can be spaced apart from the thin film transistor TR. The recessed portion 116a can provide a space for holding adhesive for attaching a light-emitting element. Also, the recessed portion 116a can be coated or lined with a reflective electrode, which can help increase brightness and light extraction, and reduce power consumption.

A depth of the recessed portion 116a can be equal to a thickness of the first planarization layer 116. Accordingly, a top surface of the passivation layer 115 can be exposed through the recessed portion 116a. For example, the recessed portion 116a can be a hole that extends all the way through the planarization layer 116. However, embodiments of the present disclosure are not limited thereto, and in other embodiments, the depth of the recessed portion 116a can be smaller than or greater than the thickness of the first planarization layer 116.

A reflection electrode 132 and a first connection electrode 134 can be provided on the first planarization layer 116 in each of the first and second pixel regions P1 and P2.

The reflection electrode 132 can overlap with the thin film transistor TR and the first and second capacitor electrodes 124 and 125. The reflection electrode 132 can be in contact with the source electrode 126 over the first and second capacitor electrodes 124 and 125 through a contact hole provided in the passivation layer 115 and the first planarization layer 116. Accordingly, the reflection electrode 132 can be electrically connected to the second capacitor electrode 125 through the source electrode 126.

In addition, the reflection electrode 132 can be disposed in the recessed portion 116a. Accordingly, the reflection electrode 132 can be in contact with top and side surfaces of the first planarization layer 116 corresponding to the recessed portion 116a. The reflection electrode 132 can also be in contact with the top surface of the passivation layer 115 exposed through the recessed portion 116a.

Meanwhile, the first connection electrode 134 can overlap with the power line 128 and can be in contact with the power line 128 through a contact hole provided in the passivation layer 115 and the first planarization layer 116. The first connection electrode 134 can be spaced apart from the recessed portion 116a.

The reflection electrode 132 and the first connection electrode 134 can be formed of a metal having relatively high reflectance. For example, the reflection electrode 132 and the first connection electrode 134 can be formed of aluminum (Al), silver (Ag), or chromium (Cr).

An adhesive layer 117 can be provided on the reflection electrode 132 in each of the first and second pixel regions P1 and P2. The adhesive layer 117 can be disposed in the recessed portion 116a and may not be disposed on the first planarization layer 116 excluding the recessed portion 116a. The adhesive layer 117 can fix the light-emitting element 140 that is transferred thereon.

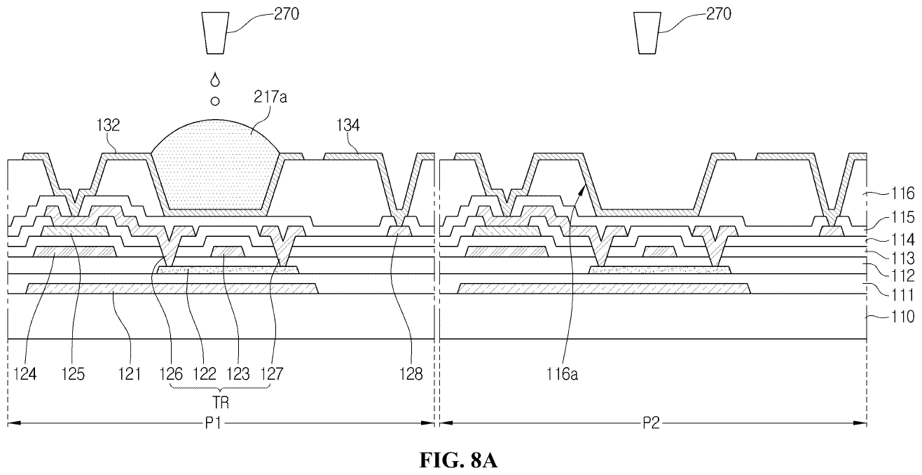

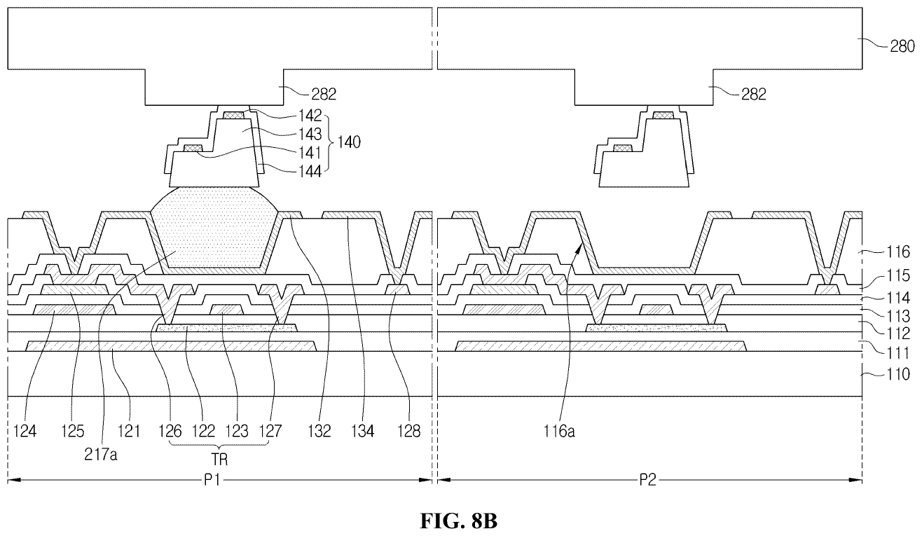

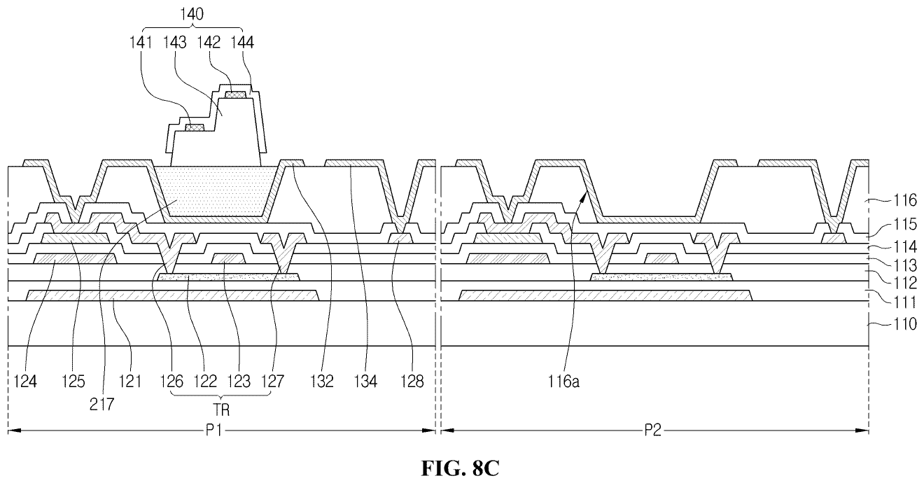

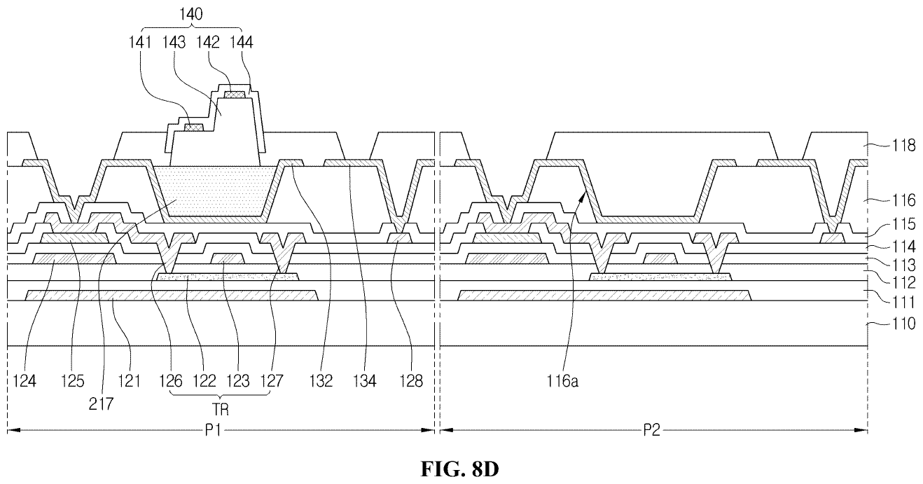

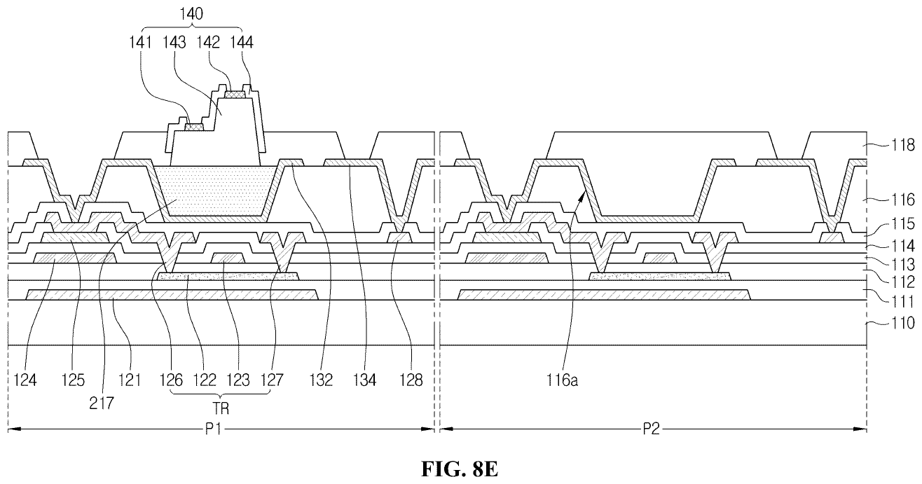

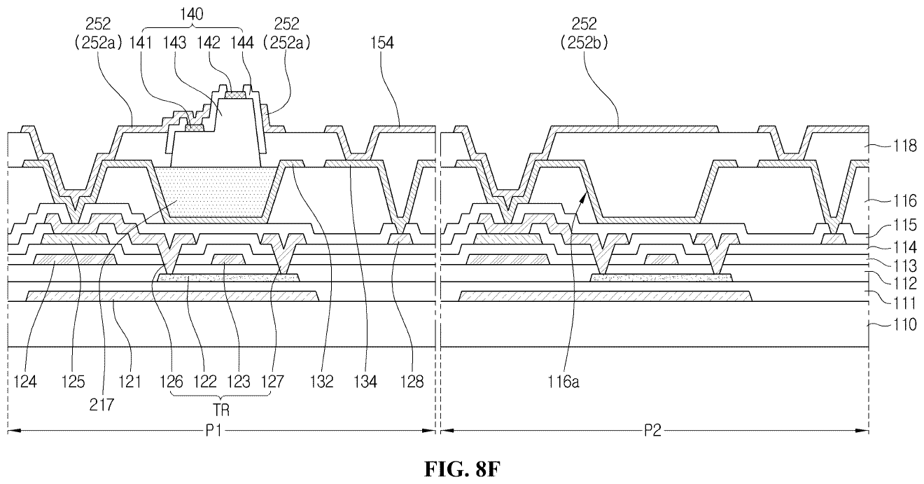

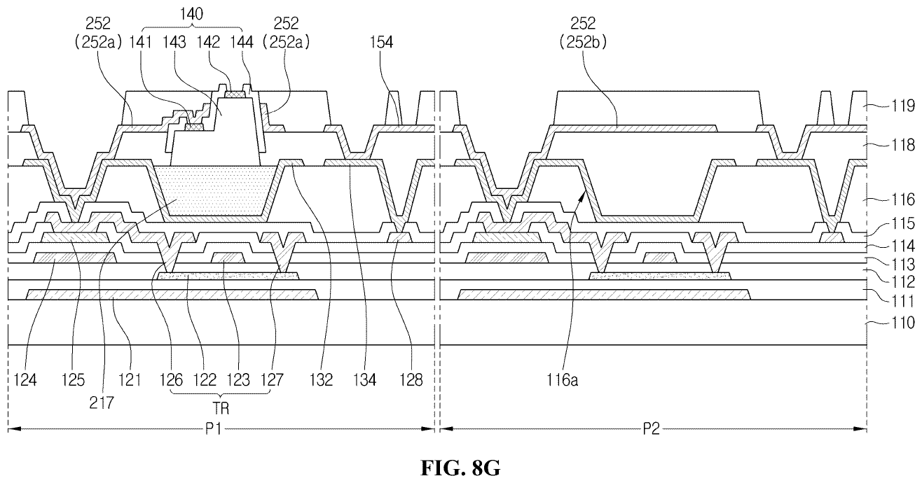

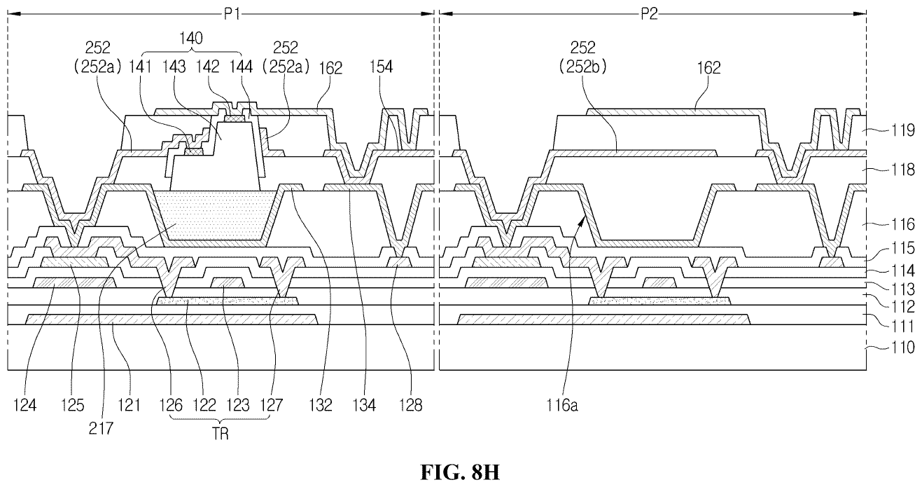

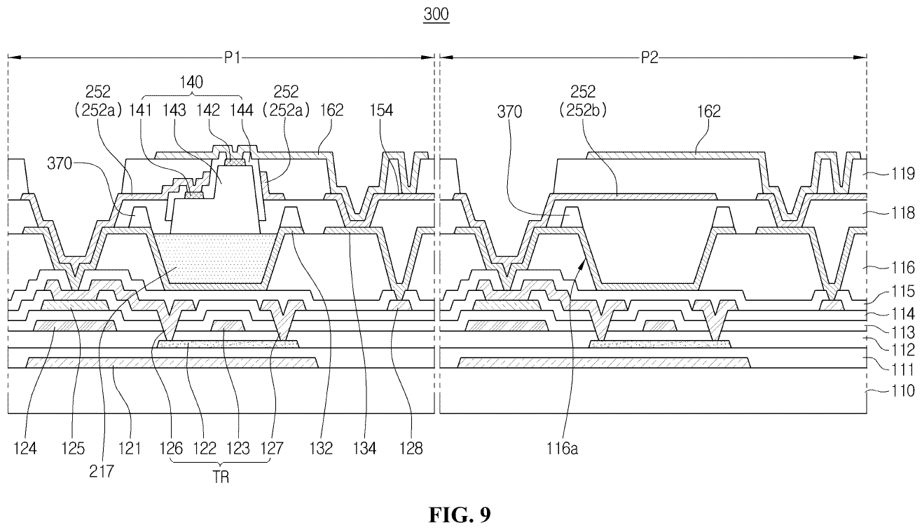

As shown in FIG. 2, the adhesive layer 117 can have a flat top surface, but embodiments of the present disclosure are not limited thereto. As shown in FIG. 8B, the top surface of the adhesive layer 117 can have a convex shape with a flat portion under the light-emitting element 140. For example, the adhesive layer 117 can be formed of an organic insulating material such as photosensitive acrylic polymer (photo acryl). Alternatively, the adhesive layer 117 can be formed of one of a polyimide (PI) resin, an epoxy resin, a urethane resin, and a polydimethylsiloxane (PDMS) resin.

The light-emitting element 140 can be provided on the adhesive layer 117 in each of the first and second pixel regions P1 and P2. The light-emitting element 140 can be disposed to correspond to the recessed portion 116a and can overlap with the reflection electrode 132. In addition, the light-emitting element 140 can also overlap with the thin film transistor TR and the light-shielding layer 121.

The light-emitting element 140 can be provided in the form of a micro light-emitting diode chip (micro LED chip or uLED chip) including an n-electrode, an n-type layer, an active layer, a p-type layer, and a p-electrode. The light-emitting element 140 can have a lateral structure in which the n-electrode and the p-electrode are provided on the same side (for example, a second side opposite to a first side facing the substrate 110) and light is emitted through the second side provided with the n-electrode and the p-electrode (for example, the second side opposite to the first side facing the substrate 110).

However, embodiments of the present disclosure are not limited thereto. In other embodiments, the light-emitting element 140 can have a flip-chip structure in which the n-electrode and the p-electrode are provided on the same side (for example, the first side facing the substrate 110) and light is emitted through the second side opposite to the first side provided with the n-electrode and the p-electrode. Alternatively, the light-emitting element 140 can have a vertical structure in which the n-electrode and the p-electrode are provided on opposite sides (for example, a first side facing the substrate 110 and a second side opposite to the first side), respectively.

The light-emitting element 140 can include a first element electrode 141, a second element electrode 142, a semiconductor layer 143, and a protection layer 144.

The first element electrode 141 and the second element electrode 142 can be provided on the semiconductor layer 143 and can be spaced from each other. The semiconductor layer 143 can have a step difference at its top surface. The first element electrode 141 and the second element electrode 142 can be disposed at different heights. For example, the second element electrode 142 can be disposed higher than the first element electrode 141. For example, the step difference on the top surface of the semiconductor layer 143 serves can expose different regions of the semiconductor material at distinct vertical planes. This can allow the first and second element electrodes to be disposed at different heights which can help ensure that they form proper and isolated electrical contacts with the respective p-type and n-type regions of the semiconductor. In this way, secure connections can be formed for causing the element to emit light, while the physical separation can help prevent short-circuits.

Here, the first element electrode 141 can be an n-electrode, and the second element electrode 142 can be a p-electrode. The first element electrode 141 can be a cathode, and the second element electrode 142 can be an anode.

However, embodiments of the present disclosure are not limited thereto. Alternatively, in other embodiments, the first element electrode 141 can be a p-electrode, and the second element electrode 142 can be an n-electrode. In this situation, the first element electrode 141 can be an anode, and the second element electrode 142 can be a cathode.

The first element electrode 141 and the second element electrode 142 can be formed of a conductive material. For example, the first element electrode 141 and the second element electrode 142 can be formed of a transparent conductive material such as indium tin oxide (ITO) or indium zinc oxide (IZO). However, embodiments of the present disclosure are not limited thereto, and in other embodiments, the first element electrode 141 and the second element electrode 142 can be formed of a metal material such as titanium (Ti), gold (Au), silver (Ag), copper (Cu), or an alloy thereof.

The semiconductor layer 143 can include a first semiconductor layer, a light-emitting layer, and a second semiconductor layer. The first semiconductor layer and the second semiconductor layer can be formed by doping n-type or p-type impurities into a semiconductor material. For example, the first semiconductor layer and the second semiconductor layer can be formed by doping n-type or p-type impurities into gallium nitride (GaN), indium aluminum phosphide (InAlP), or gallium arsenide (GaAs). In addition, for example, the n-type impurities can be silicon (Si), germanium (Ge), or tin (Sn), and the p-type impurities can be magnesium (Mg), zinc (Zn), or beryllium (Be). However, embodiments of the present disclosure are not limited thereto.

The light-emitting layer can be disposed between the first semiconductor layer and the second semiconductor layer. The light-emitting layer can receive electrons and holes from the first semiconductor layer and the second semiconductor layer, respectively, and emit light. The light-emitting layer can be formed of a single quantum well (SQW) structure or a multi quantum well (MQW) structure. For example, the light-emitting layer can be formed of indium gallium nitride (InGaN) or gallium nitride (GaN), but is not limited thereto.

The protection layer 144 can be provided on the first element electrode 141, the second element electrode 142, and the semiconductor layer 143. The protection layer 144 can cover and protect the first element electrode 141, the second element electrode 142, and the semiconductor layer 143, and the protection layer 144 can partially expose top surfaces of the first element electrode 141 and the second element electrode 142.

The protection layer 144 can be formed as a single layer or multiple layers of an inorganic insulating material. For example, the inorganic insulating material of the protection layer 144 can include silicon nitride (SiNx), silicon oxide (SiOx), or silicon oxynitride (SiON).

Next, a second planarization layer 118 can be provided on the adhesive layer 117 provided with the light-emitting element 140 thereon. The second planarization layer 118 can be disposed substantially all over the substrate 110.

The second planarization layer 118 can surround a portion of a side surface of the light-emitting element 140 to fix and protect the light-emitting element 140. A thickness of the second planarization layer 118 can be smaller than a thickness of the light-emitting element 140. The second planarization layer 118 can expose the first element electrode 141 and the second element electrode 142.

The second planarization layer 118 can be formed of an organic insulating material such as photosensitive acrylic polymer (photo acryl). The second planarization layer 118 can have a substantially flat top surface.

A first electrode 152 and a second connection electrode 154 can be provided on the second planarization layer 118 in each of the first and second pixel regions P1 and P2.

The first electrode 152 can overlap with the light-emitting element 140. The first electrode 152 can be in contact with the first element electrode 141 of the light-emitting element 140 and can be spaced apart from the second element electrode 142 of the light-emitting element 140. The first electrode 152 can have an opening corresponding to the second element electrode 142.

The first electrode 152 can overlap with the recessed portion 116a and the adhesive layer 117 in the recessed portion 116a.

In addition, the first electrode 152 can overlap with the reflection electrode 132 and can be in contact with the reflection electrode 132 through a contact hole provided in the second planarization layer 118. Accordingly, the first electrode 152 can be electrically connected to the source electrode 126 of the thin film transistor TR and the second capacitor electrode 125 through the reflection electrode 132. The first element electrode 141 of the light-emitting element 140 can be electrically connected to the source electrode 126 of the thin film transistor TR and the second capacitor electrode 125 through the first electrode 152 and the reflection electrode 132.

The second connection electrode 154 can overlap with the first connection electrode 134 and can be in contact with the first connection electrode 134 through a contact hole provided in the second planarization layer 118. Accordingly, the second connection electrode 154 can be electrically connected to the power line 128 through the first connection electrode 134.

The first electrode 152 and the second connection electrode 154 can be formed of a transparent conductive material such as indium tin oxide (ITO) or indium zinc oxide (IZO). Alternatively, the first electrode 152 and the second connection electrode 154 can be formed of a metal such as aluminum (Al), copper (Cu), molybdenum (Mo), titanium (Ti), chromium (Cr), nickel (Ni), tungsten (W), or an alloy thereof.

A third planarization layer 119 can be provided on the first electrode 152 and the second connection electrode 154. The third planarization layer 119 can be disposed substantially all over the substrate 110.

The third planarization layer 119 can surround a portion of the side surface of the light-emitting element 140 to flatten or planarize a top surface of the substrate 110 on which the light-emitting element 140 is disposed together with the second planarization layer 118 and to fix and protect the light-emitting element 140 together with the adhesive layer 117 and the second planarization layer 118.

The third planarization layer 119 can cover the light-emitting element 140 and the first electrode 152 and can expose a part of the light-emitting element 140. Specifically, the third planarization layer 119 can cover the first element electrode 141 of the light-emitting element 140 and the first electrode 152 and can expose the second element electrode 142 of the light-emitting element 140. In addition, the third planarization layer 119 can partially expose the second connection electrode 154.

The third planarization layer 119 can be formed of an organic insulating material such as photosensitive acrylic polymer (photo acryl).

Next, a second electrode 162 can be provided on the third planarization layer 119 in each of the first and second pixel regions P1 and P2. The second electrode 162 can overlap with the light-emitting element 140, the first electrode 152, and the second connection electrode 154.

Specifically, the second electrode 162 can overlap with the first and second element electrode 141 and 142 of the light-emitting element 140 and can be in contact with the exposed second element electrode 142. In addition, the second electrode 162 can also overlap with the first electrode 152 and thus overlap with the reflection electrode 132 and the recessed portion 116a.

The second electrode 162 can extend to overlap with the second connection electrode 154. The second electrode 162 can be in contact with the second connection electrode 154 through a contact hole provided in the third planarization layer 119. Accordingly, the second electrode 162 can be electrically connected to the first connection electrode 134 through the second connection electrode 154. The second element electrode 142 of the light-emitting element 140 can be electrically connected to the power line 128 through the second electrode 162 and the first and second connection electrodes 134 and 154.

In this situation, the second electrode 162 can be in contact with the second connection electrode 154 through at least two contact holes, thereby improving contact properties between the second electrode 162 and the second connection electrode 154.

The second electrode 162 can be formed of a transparent conductive material such as indium tin oxide (ITO) or indium zinc oxide (IZO). Alternatively, the second electrode 162 can be formed of a metal such as aluminum (Al), copper (Cu), molybdenum (Mo), titanium (Ti), chromium (Cr), nickel (Ni), tungsten (W), or an alloy thereof.

As such, in the display device according to the first embodiment of the present disclosure, by providing the recessed portion 116a in the first planarization layer 116 of each of the first and second pixel regions P1 and P2, providing the adhesive layer 117 in the recessed portion 116a, and transferring the light-emitting element 140 on the adhesive layer 117, the light-emitting element 140 can be easily and securely transferred to a desired region.

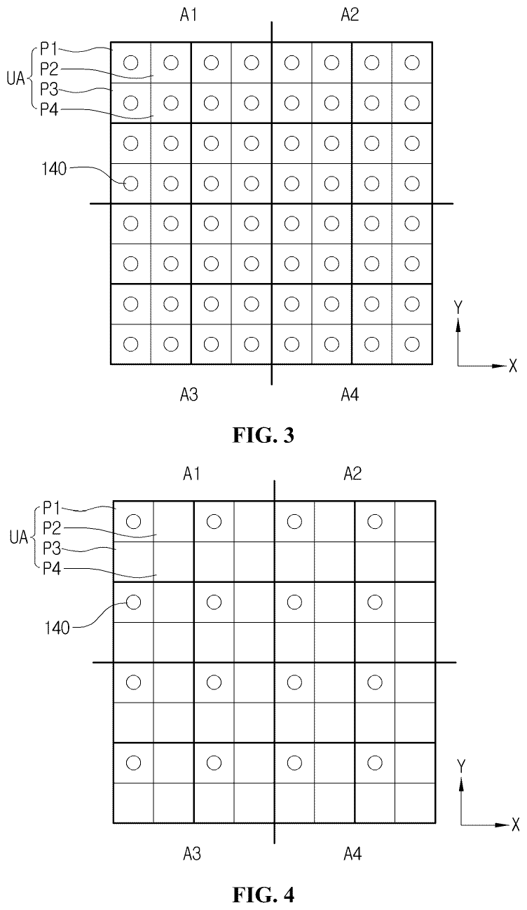

Meanwhile, in embodiments of the present disclosure, by selectively providing the adhesive layer 117 in the recessed portion 116a, it is possible to implement display devices of different resolutions and/or sizes. In other words, according to embodiments, this type of configuration can provide a type of base structure that can allow for the manufacturing of display screens with different resolutions or sizes using a single, standardized panel design. For example, the configuration can include selectively placing an adhesive layer (and therefore a corresponding light-emitting element) only into specific, designated pixel locations, such as into every other recessed portion or into every third recessed portion, etc. In this way, by choosing which potential pixel locations to populate with a light source and which to leave empty, a manufacturer can flexibly customize the final pixel pitch and active display area for different products without having to re-engineer the entire panel each time. The display devices of different resolutions and/or sizes will be described with reference to FIG. 3 and FIG. 4. Here, the resolution can be expressed in PPI (pixel per inch), which is the number of pixels per inch.

FIG. 3 is a schematic view showing a part of a first display device according to an embodiment of the present disclosure (e.g., full resolution or max resolution configuration), and FIG. 4 is a schematic view showing a part of a second display device according to an embodiment of the present disclosure (e.g., a ¼^{th} resolution configuration). For example, the first display device of FIG. 3 and the second display device of FIG. 4 can have the same size panel, but different resolutions. The first display device of FIG. 3 can be a high resolution display device, and the second display device of FIG. 4 can be a low resolution display device. Alternatively, the first display device of FIG. 3 and the second display device of FIG. 4 can have the same resolution and different sizes. The first display device of FIG. 3 can be a high PPI display device, and the second display device of FIG. 4 can be a low PPI display device and can have a larger size than the first display device of FIG. 3.

In FIG. 3 and FIG. 4, each of the first and second display devices according to the embodiment of the present disclosure can include first, second, third, and fourth areas A1, A2, A3, and A4. Each of the first, second, third, and fourth areas A1, A2, A3, and A4 can be a tiling panel. A plurality of tiling panels can be manufactured individually and then connected to each other, thereby implementing a display device.

In each of the first, second, third, and fourth areas A1, A2, A3, and A4, a plurality of unit area UA can be provided in a first direction X and a second direction Y. For example, one unit area UA can include first, second, third, and fourth pixel regions P1, P2, P3, and P4 adjacent to each other in the first direction X and the second direction Y. Each of the first, second, third, and fourth pixel regions P1, P2, P3, and P4 can correspond to one pixel and can include a plurality of sub-pixels.

As shown in FIG. 3, in the first display device, the light-emitting element 140 can be provided in each of the first, second, third, and fourth pixel regions P1, P2, P3, and P4. For example, when the pixel includes three sub-pixels, three light-emitting elements can be provided in each of the first, second, third, and fourth pixel regions P1, P2, P3, and P4. For example, one unit area UA can include 12 subpixel according to this configuration, but embodiments are not limited thereto.

Each of the first, second, third, and fourth pixel regions P1, P2, P3, and P4 of the first display device can have the same cross-sectional configuration as the first pixel region P1 or the second pixel region P2 of FIG. 2.

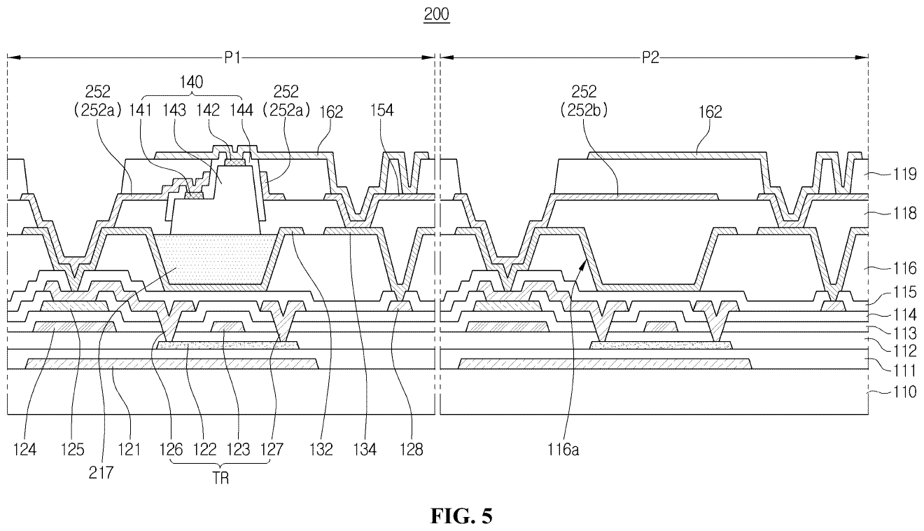

Alternatively, as shown in FIG. 4, in the second display device, the light-emitting element 140 can be provided only in one of the first, second, third, and fourth pixel regions P1, P2, P3, and P4, for example, only in the first pixel region P1 while the second, third, and fourth pixel regions P2, P3, and P4 remain free of any light-emitting elements (e.g., no light-emitting element in P2, P3 and P4). The first pixel region P1 of the second display device can have the same cross-sectional configuration as the first pixel region P1 or the second pixel region P2 of FIG. 2. The second, third, and fourth pixel regions P2, P3, and P4 of the second display device can have the configuration of the first pixel region P1 of FIG. 2 without the adhesive layer 117, without the light-emitting element 140, and without the first electrode 152 and can have substantially the same cross-sectional configuration as the second pixel region P2 of FIG. 5 to be described later.

Accordingly, when the sizes of the first and second display devices are the same, the first display device of FIG. 3 can include a greater number of light-emitting elements 140 than the second display device of FIG. 4.

On the other hand, when the resolutions of the first and second display devices are the same, the second display device of FIG. 4 can include a larger size than the first display device of FIG. 3.

The configuration of the low resolution or low PPI display device of FIG. 4 will be described in detail with reference to accompanying drawings.

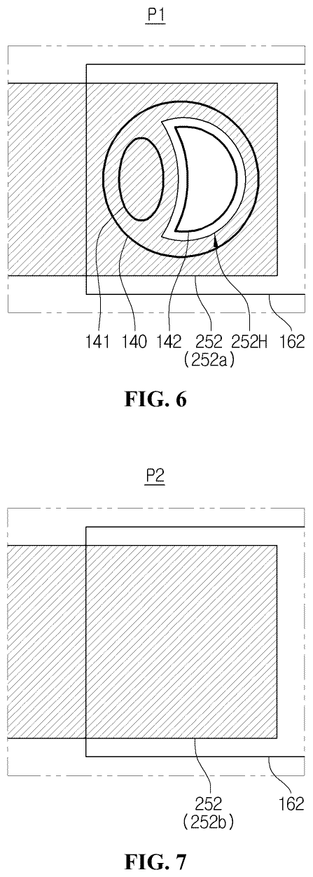

FIG. 5 is a schematic cross-sectional view of a display panel of a display device according to a second embodiment of the present disclosure and shows first and second pixel regions adjacent to each other. FIG. 6 and FIG. 7 are schematic plan views of a display panel of a display device according to the second embodiment of the present disclosure. FIG. 6 shows the first pixel region, and FIG. 7 shows the second pixel region.

The display device according to the second embodiment of the present disclosure has substantially the same configuration as that of the first embodiment, except for that the adhesive layer, the light-emitting element, and the first electrode are absent from the second pixel region. The same parts as those of the first embodiment are designated by the same or similar reference signs, and explanation for the same parts can be shortened or omitted.

In FIG. 5, a display panel 200 of a display device according to the second embodiment of the present disclosure can include a substrate 110 provided with a first pixel region P1 and a second pixel region P2. The first pixel region P1 and the second pixel region P2 can have substantially the same configuration except for an adhesive layer 217, a light-emitting element 140, and a first electrode 252 which are only in the first pixel region P1. For example, in this configuration, the second pixel region P2, which intentionally lacks a light-emitting element, can be referred to by several names, such as an empty pixel region, a dummy pixel, an inactive pixel site, or a non-emissive region, which can reflect its non-functional role in producing light, but embodiments are not limited thereto.

For example, the adhesive layer 217 and the light-emitting element 140 can be provided only in the first pixel region P1, and an adhesive layer and a light-emitting element may not be provided in the second pixel region P2.

Specifically, a thin film transistor TR can be provided in each of the first pixel region P1 and the second pixel region P2. A passivation layer 115 can be provided on the thin film transistor TR. A first planarization layer 116 having a recessed portion 116a can be provided on the passivation layer 115 in each of the first and second pixel regions P1 and P2.

A reflection electrode 132 and a first connection electrode 134 can be provided on the first planarization layer 116 in each of the first and second pixel regions P1 and P2. The reflection electrode 132 can overlap with the recessed portion 116a and can also be disposed in the recessed portion 116a. The first connection electrode 134 can be spaced apart from the recessed portion 116a.

The adhesive layer 217 can be provided on the reflection electrode 132 in the first pixel region P1, and no adhesive layer is provided in the second pixel region P2, according to an embodiment. In the first pixel region P1, the adhesive layer 217 can be disposed in the recessed portion 116a and may not be disposed on the first planarization layer 116 excluding the recessed portion 116a. In other words, the second pixel region P2 does not have any adhesive layer nor any light-emitting element, rather it is an empty pixel region or a dummy pixel.

The light-emitting element 140 can be provided on the adhesive layer 217 in the first pixel region P1, and no light-emitting element is provided in the second pixel region P2 (e.g., the second pixel region P2 does not have a light-emitting element). In the first pixel region P1, the light-emitting element 140 can be disposed to correspond to the recessed portion 116a and can overlap with the reflection electrode 132.

A second planarization layer 118 can be provided on the adhesive layer 217 provided with the light-emitting element 140 thereon. The second planarization layer 118 can be disposed substantially all over the substrate 110. Accordingly, the second planarization layer 118 can be disposed in both the first pixel region P1 and the second pixel region P2.

In the first pixel region P1, the second planarization layer 118 can surround a portion of a side surface of the light-emitting element 140 to fix and protect the light-emitting element 140.

Meanwhile, in the second pixel region P2, the second planarization layer 118 can be in contact with the reflection electrode 132 and can be disposed in the recessed portion 116a.

The first electrode 252 and a second connection electrode 154 can be provided on the second planarization layer 118 in each of the first and second pixel regions P1 and P2. Here, the first electrode 252a of the first pixel region P1 can have a different configuration from the first electrode 252b of the second pixel region P2.

Specifically, the first electrode 252a of the first pixel region P1 can overlap with the light-emitting element 140. The first electrode 252a of the first pixel region P1 can overlap and be in contact with a first element electrode 141 of the light-emitting element 140 and can be spaced apart from a second element electrode 142 of the light-emitting element 140. As shown in FIG. 6, the first electrode 252a of the first pixel region P1 can have an opening 252H corresponding to the second element electrode 142, and the second element electrode 142 can be disposed in the opening 252H.

On the other hand, in the second pixel region P2, since no light-emitting element is provided, the first electrode 252b of the second pixel region P2 may not overlap a light-emitting element. As shown in FIG. 7, the first electrode 252b of the second pixel region P2 may not have an opening, instead it has a solid rectangular shape.

Next, a third planarization layer 119 can be provided on the first electrode 252 and the second connection electrode 154, and a second electrode 162 can be provided on the third planarization layer 119 in each of the first and second pixel regions P1 and P2.

In the first pixel region P1, the second electrode 162 can overlap with the first electrode 252a having the opening 252H and the light-emitting element 140 and can be in contact with the second element electrode 142 of the light-emitting element 140. On the other hand, in the second pixel region P2, the second electrode 162 can overlap with the first electrode 252b without the opening.

As such, in the display device according to the second embodiment of the present disclosure, among the first and second pixel regions P1 and P2 having substantially the same configuration, by providing the adhesive layer 217 and the light-emitting element 140 only in the recessed portion 116a of the first pixel region P1, it is possible to implement a low resolution or low PPI display device.

A method of manufacturing the display device according to the second embodiment of the present disclosure will be described with reference to FIGS. 8A to 8H.

FIGS. 8A to 8H are schematic cross-sectional views of a display panel of a display device in steps of manufacturing the same according to the second embodiment of the present disclosure and will be described with reference to FIG. 6 and FIG. 7 together.

In FIG. 8A, by repeating steps of depositing a thin film and selectively removing it through a photolithography process, the light-shielding layer 121, the buffer layer 111, the active layer 122, the gate insulation layer 112, the gate electrode 123 and the first capacitor electrode 124, the first interlayer insulation layer 113, the second capacitor electrode 125, the second interlayer insulation layer 114, and the source and drain electrodes 126 and 127 and the power line 128 can be sequentially formed on the substrate 110 provided with the first pixel region P1 and the second pixel region P2.

Next, the passivation layer 115 can be formed on the source electrode 126, the drain electrode 127, and the power line 128 by depositing an inorganic insulating material, and the first planarization layer 116 can be formed on the passivation layer 115 by applying an organic insulating material.

Then, portions of the first planarization layer 116 can be selectively removed through a photolithography process, thereby forming the recessed portion 116a in each of the first and second pixel regions P1 and P2. In addition, the first planarization layer 116 and the passivation layer 115 thereunder can be selectively patterned, thereby forming the contact holes exposing the source electrode 126 and the power line 128.

Next, the reflection electrode 132 and the first connection electrode 134 can be formed on the first planarization layer 116 in each of the first and second pixel regions P1 and P2 by depositing a conductive material and then patterning it through a photolithography process. The reflection electrode 132 can overlap with the recessed portion 116a and can be disposed in the recessed portion 116a.

Next, a coating equipment 270 can be disposed over the substrate 110 provided with the reflection electrode 132, and an adhesive material can be applied only to the first pixel region P1, thereby forming the adhesive material layer 217a in the recessed portion 116a of the first pixel region P1. In this situation, an adhesive material layer may not be formed in the recessed portion 116a of the second pixel region P2. For example, the second pixel region P2 can correspond to an empty pixel region or a dummy pixel.

For example, the coating equipment 270 can be an inkjet equipment including a nozzle, but embodiments of the present disclosure are not limited thereto.

Next, in FIG. 8B, a stamp 280 provided with light-emitting elements 140 can be disposed over the substrate 110 provided with the adhesive material layer 217a, and the stamp 280 and the substrate 110 can be attached together such that the light-emitting element 140 can be in contact with the adhesive material layer 217a.

Here, the stamp 280 can have a plurality of protruding portions 282 at its bottom surface, and the light-emitting element 140 can be adhered to each protruding portion 282 through a plurality of transferring steps.

Next, in FIG. 8C, the adhesive material layer 217a can be cured, thereby forming the adhesive layer 217 and fixing the light-emitting element 140 on the substrate 110. Then, the stamp 280 can be detached from the substrate 110, so that the light-emitting element 140 can be transferred onto the adhesive layer 217 formed in the recessed portion 116a of the first pixel region P1.

Meanwhile, since an adhesive material layer is not formed in the second pixel region P2, the first pixel region P1 and the second pixel region P2 can have a height different on the substrate 110, and in FIG. 8C, the light-emitting element 140 of the stamp 280 corresponding to the second pixel region P2 may not be in contact with any component provided over the substrate 110 in the second pixel region P2. Accordingly, no light-emitting element is transferred in the second pixel region P2, according to an embodiment. For example, the second pixel region P2 can correspond to an empty pixel region or a dummy pixel.

Here, the protection layer 144 of the light-emitting element 140 can cover the first and second element electrodes 141 and 142 without exposing them.

Next, in FIG. 8D, the second planarization layer 118 can be formed over the substrate 110 on which the light-emitting element 140 is transferred by applying an organic insulating material, and can be patterned through a photolithography process, thereby selectively exposing top surfaces of the reflection electrode 132 and the first connection electrode 134. Then, the second planarization layer 118 can be partially removed from its top surface through an ashing process. Accordingly, a thickness of the second planarization layer 118 can be decreased, and the second planarization layer 118 can expose the protection layer 144 on the first and second element electrodes 141 and 142 of the light-emitting element 140. In this situation, a width of the second planarization layer 118 can also be decreased through the ashing process together with the thickness of the second planarization layer 118.

Next, in FIG. 8E, portions of the protection layer 144 on the light-emitting element 140 can be selectively removed, thereby exposing the first and second element electrodes 141 and 142 of the light-emitting element 140. The protection layer 144 can be removed through a dry etching process. In this situation, a photoresist pattern can be formed on the second planarization layer 118 to cover the substrate 110 excluding the light-emitting element 140 and can be removed after the first and second element electrodes 141 and 142 are exposed.

Next, in FIG. 8F, the first electrode 252 and the second connection electrode 154 can be formed in each of the first and second pixel regions P1 and P2 by depositing a conductive material on the light-emitting element 140 and the second planarization layer 118 and patterning it through a photolithography process.

Here, as shown in FIG. 6, the first electrode 252a of the first pixel region P1 can have the opening 252H corresponding to the second element electrode 142, and as shown in FIG. 7, the first electrode 252b of the second pixel region P2 may not have an opening.

Next, in FIG. 8G, the third planarization layer 119 can be formed on the first electrode 252 and the second connection electrode 154 by applying an organic insulating material and can be patterned through a photolithography process, thereby forming the contact hole that expose the second connection electrode 154 in each of the first and second pixel regions P1 and P2. In this situation, the third planarization layer 119 can expose the first electrode 252 in each of the first and second pixel regions P1 and P2 and can cover the second element electrode 142 in the first pixel region P1.

Then, the third planarization layer 119 can be partially removed from its top surface through an ashing process. Accordingly, the thickness of the third planarization layer 119 can be decreased, thereby exposing the second element electrode 142 of the light-emitting element 140. In this situation, a width of the third planarization layer 119 can also be decreased through the ashing process together with the thickness of the third planarization layer 119.

Next, in FIG. 8H, the second electrode 162 can be formed on the third planarization layer 119 in each of the first and second pixel regions P1 and P2 by depositing a conductive material and then patterning it through a photolithography process. The second electrode 162 can be in contact with the second connection electrode 154 through the contact hole of the third planarization layer 119 in each of the first and second pixel regions P1 and P2.

Meanwhile, in the first pixel region P1, the second electrode 162 can cover the light-emitting element 140 and can be in contact with the exposed second element electrode 142 of the light-emitting element 140. Additionally, in the first pixel region P1, the second electrode 162 can overlap with the first electrode 252a having the opening 252H.

On the other hand, in the second pixel region P2, the second electrode 162 can overlap with the first electrode 252b without an opening.

As such, in the method of manufacturing the display device according to the second embodiment of the present disclosure, by forming the adhesive layer 217 only in the recessed portion 116a of the first pixel region P1, only the light-emitting element 140 corresponding to the first pixel region P1 can be transferred from the stamp 280 to the substrate 110 and the second pixel region P2 does not receive any light-emitting element, so that a low resolution or low PPI display device can be manufactured.

Meanwhile, the light-emitting element 140 of FIG. 8B that is not transferred to the substrate 110, that is, in FIG. 8B, the light-emitting element 140 on the stamp 280 corresponding to the second pixel region P2 can be used to manufacture another low resolution or low PPI display device, which can reduce waste and improve manufacturing efficiencies.

For example, a stamp provided with light-emitting elements for forming one high resolution or high PPI display device of FIG. 3 can also be used to form four low resolution or low PPI display devices.

A display device according to an embodiment of the present disclosure can further include a dam structure. Such a display device according to a third embodiment of the present disclosure will be described with reference to FIG. 9.

FIG. 9 is a schematic cross-sectional view of a display panel of a display device according to a third embodiment of the present disclosure and shows first and second pixel regions adjacent to each other. The display device according to the third embodiment of the present disclosure has substantially the same configuration as those of the first and second embodiments, except for a dam structure. The same parts as those of the first and second embodiments are designated by the same or similar reference signs, and explanation for the same parts can be shortened or omitted.

In FIG. 9, a display panel 300 of a display device according to the third embodiment of the present disclosure can include a substrate 110 provided with a first pixel region P1 and a second pixel region P2. The first pixel region P1 and the second pixel region P2 can have substantially the same configuration except for an adhesive layer 217, a light-emitting element 140, and a first electrode 252.

For example, the adhesive layer 217 and the light-emitting element 140 can be provided only in the first pixel region P1, and an adhesive layer and a light-emitting element may not be provided in the second pixel region P2. For example, the second pixel region P2 can correspond to an empty pixel region or a dummy pixel.

In addition, the first electrode 252a of the first pixel region P1 can have a different configuration from the first electrode 252b of the second pixel region P2. As shown in FIG. 6, the first electrode 252a of the first pixel region P1 can have an opening 252H corresponding to the second element electrode 142, and the second element electrode 142 can be disposed in the opening 252H. As shown in FIG. 7, the first electrode 252b of the second pixel region P2 may not have an opening.

Meanwhile, in each of the first and second pixel regions P1 and P2, a dam structure 370 can be provided between the first planarization layer 116 and the first electrode 252. The dam structure 370 can be disposed between the reflection electrode 132 and the first electrode 252, and more particularly, can be disposed between the reflection electrode 132 and the second planarization layer 118. The dam structure 370 can be placed to correspond to the recessed portion 116a and can substantially surround the recessed portion 116a. According to an embodiment, the dam structure 370 can have a closed loop shape or ring shape in a plan view.

The dam structure 370 can have a hydrophobic property. For example, the dam structure 370 can be formed of an organic insulating material having a hydrophobic property. Alternatively, the dam structure 370 can be formed of an organic insulating material having a hydrophilic property and can be subjected to a surface treatment to have a hydrophobic property.

The dam structure 370 can prevent or reduce an adhesive material, which is applied in the recessed portion 116a to form the adhesive layer 217, from overflowing to the outside of the recessed portion 116a, and the adhesive layer 217 can be easily formed only in the necessary area.

The display panel 300 of the display device according to the third embodiment of the present disclosure can be manufactured through the same processes as those in the method of manufacturing the display device according to the second embedment of FIGS. 8A to 8H, except for the step of forming the dam structure 370. The dam structure 370 can be formed between the steps of forming the reflection electrode 132 and forming the adhesive material layer 217a in FIG. 8A.

Meanwhile, the dam structure 370 can be omitted in the second pixel region P2. For example, the dam structure 370 can be formed only in the first pixel region P1.

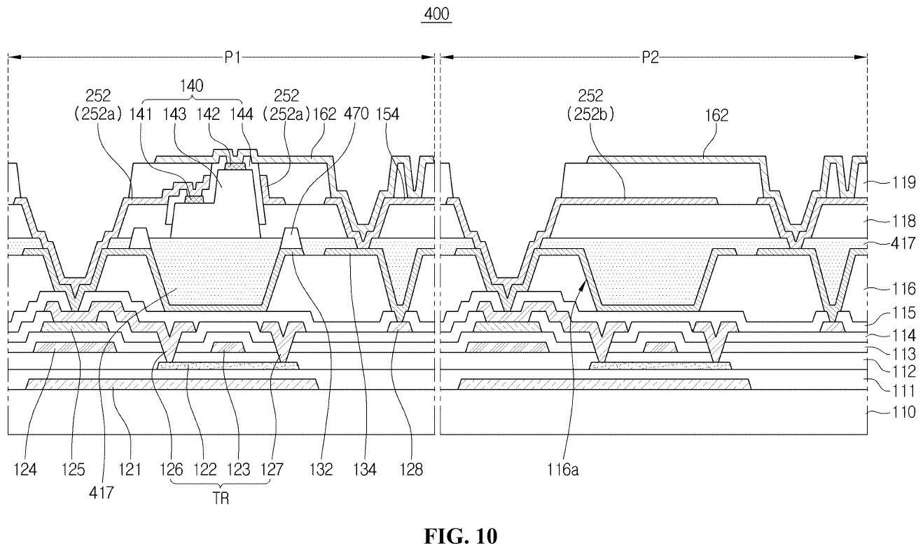

A display device according to an embodiment of the present disclosure can include adhesive layers in both the first and second pixel regions. Such a display device according to a fourth embodiment of the present disclosure will be described with reference to FIG. 10.

FIG. 10 is a schematic cross-sectional view of a display panel of a display device according to a fourth embodiment of the present disclosure and shows first and second pixel regions adjacent to each other. The display device according to the fourth embodiment of the present disclosure has substantially the same configuration as those of the first and second embodiments, except for an adhesive layer and a dam structure. The same parts as those of the first and second embodiments are designated by the same or similar reference signs, and explanation for the same parts can be shortened or omitted.

In FIG. 10, a display panel 400 of a display device according to the fourth embodiment of the present disclosure can include a substrate 110 provided with a first pixel region P1 and a second pixel region P2. The first pixel region P1 and the second pixel region P2 can have substantially the same configuration except for a dam structure 470, a light-emitting element 140, and a first electrode 252.

For example, the dam structure 470 and the light-emitting element 140 can be provided only in the first pixel region P1, and a dam structure and a light-emitting element may not be provided in the second pixel region P2. In other words, there is no dam structure in the second pixel region P2.

In addition, the first electrode 252a of the first pixel region P1 can have a different configuration from the first electrode 252b of the second pixel region P2. As shown in FIG. 6, the first electrode 252a of the first pixel region P1 can have an opening 252H corresponding to the second element electrode 142, and the second element electrode 142 can be disposed in the opening 252H. As shown in FIG. 7, the first electrode 252b of the second pixel region P2 may not have an opening.

Meanwhile, in each of the first and second pixel regions P1 and P2, an adhesive layer 417 can be provided between the reflection electrode 132 and the second planarization layer 118. In the first pixel region P1, the adhesive layer 417 can be disposed between the reflection electrode 132 and the light-emitting element 140.

The adhesive layer 417 can be disposed substantially all over the substrate 110 and may not be disposed on the dam structure 470. In this situation, to transfer the light-emitting element 140 only in the first pixel region P1, the dam structure 470 can be provided in the first pixel region P1, and no dam structure can be provided in the second pixel region P2.

Here, the adhesive layer 417 can be formed by a slit coating or spin coating method.

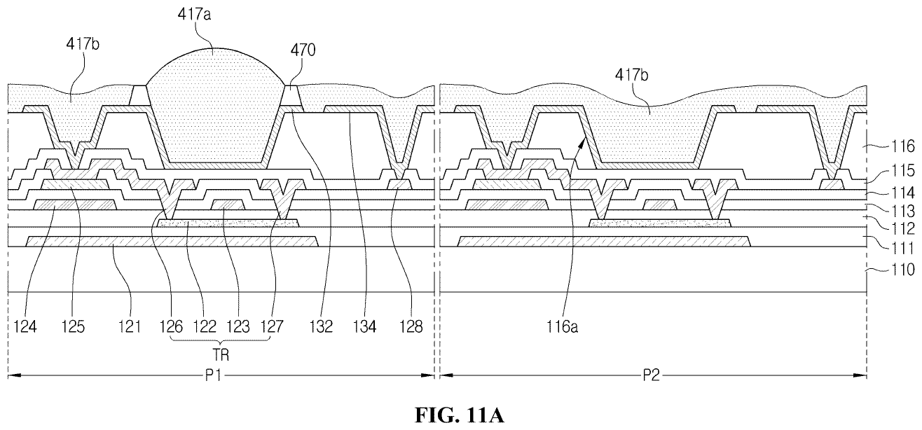

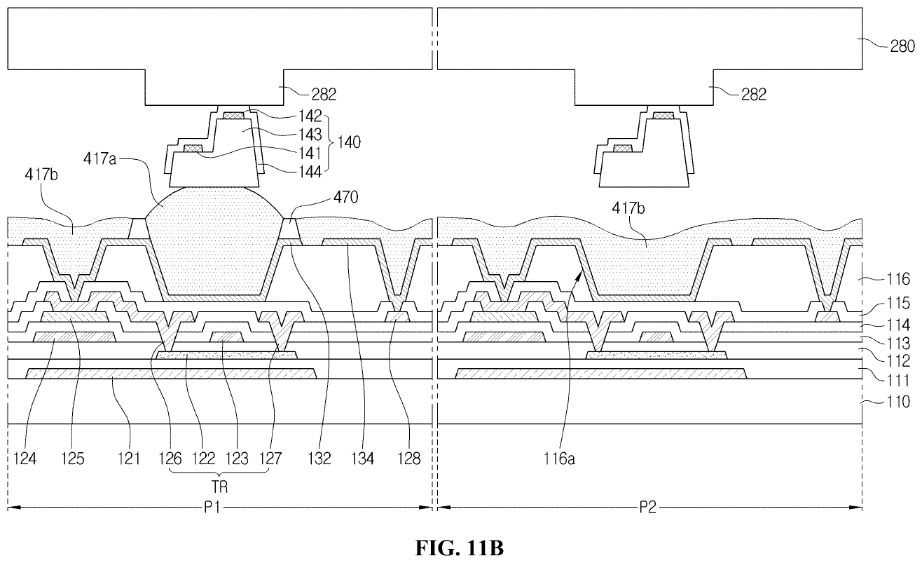

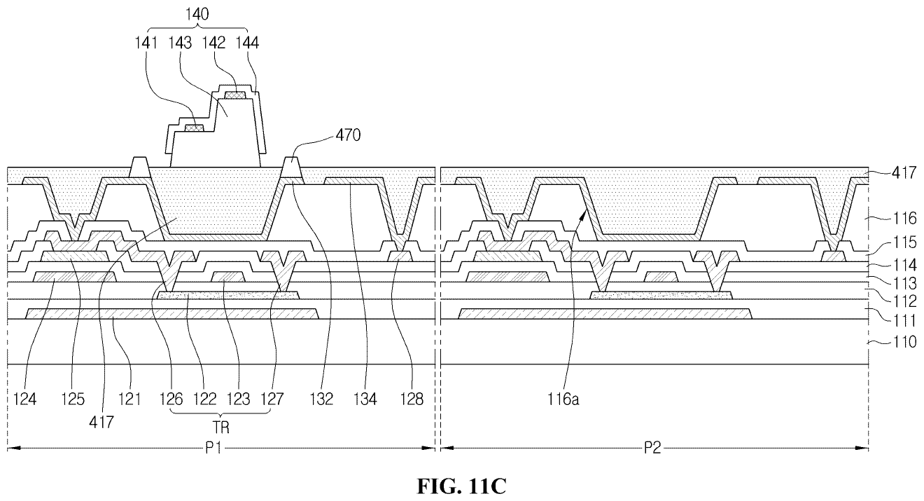

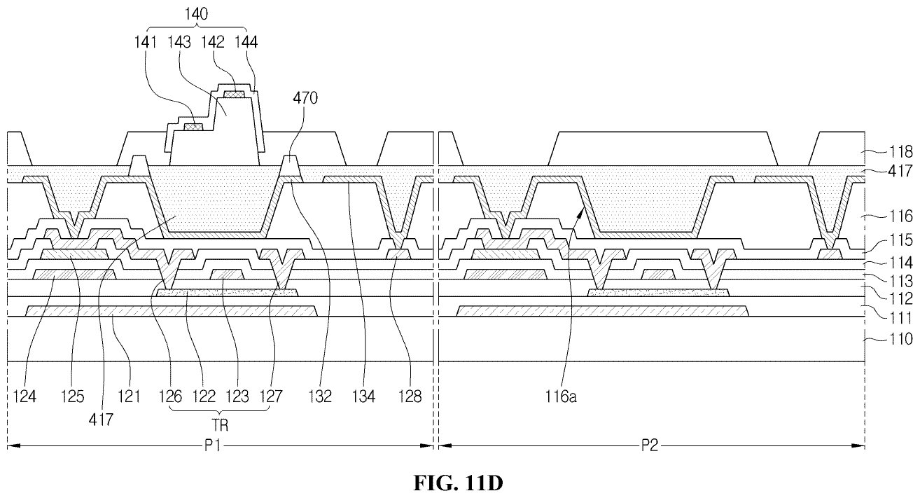

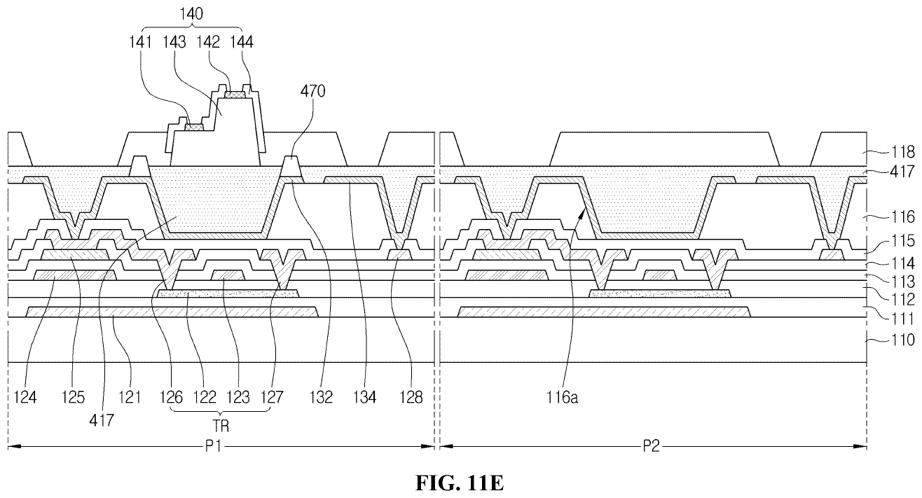

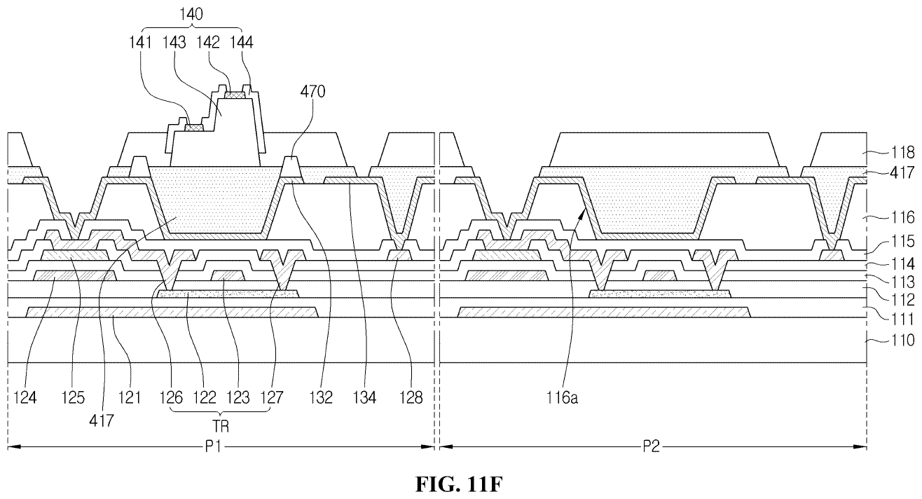

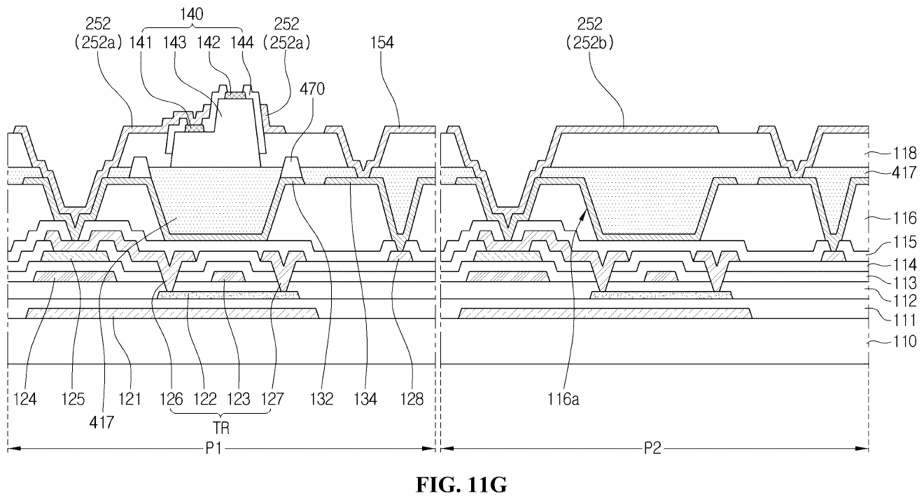

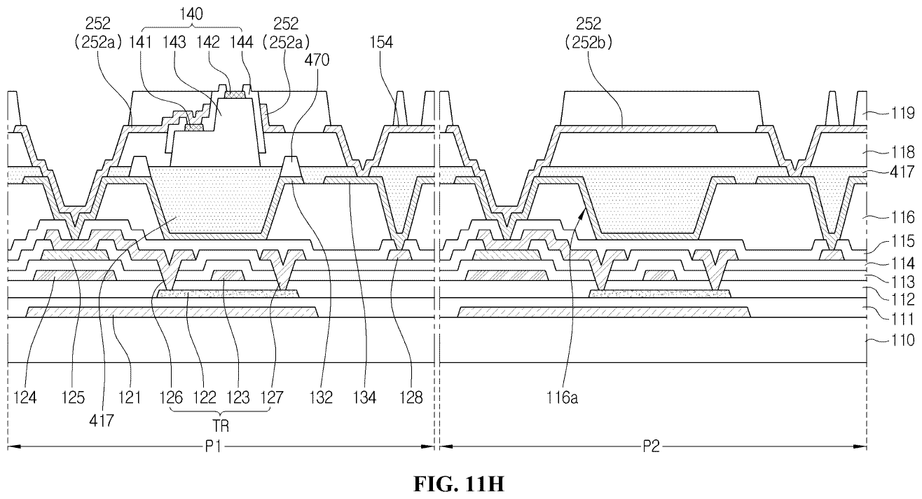

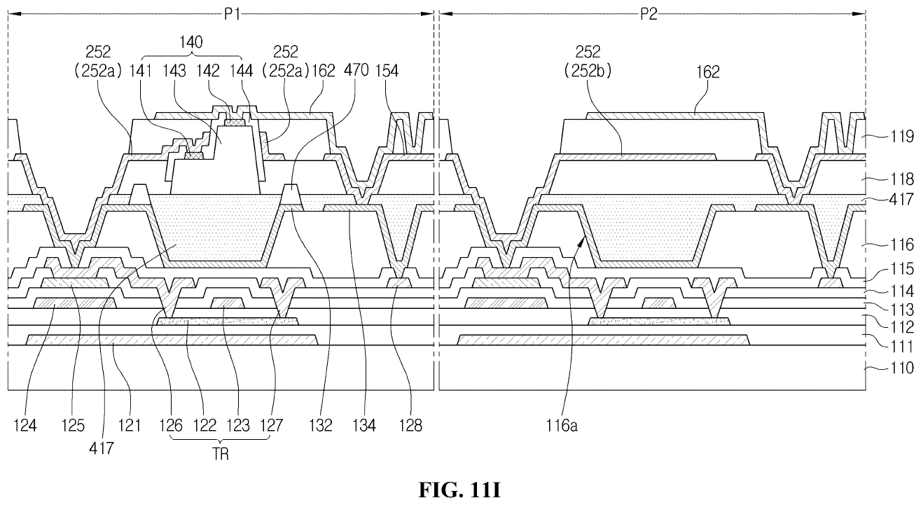

A method of manufacturing the display device according to the fourth embodiment of the present disclosure will be described with reference to FIGS. 11A to 11I.

FIGS. 11A to 11I are schematic cross-sectional views of a display panel of a display device in steps of manufacturing the same according to the fourth embodiment of the present disclosure. The method of manufacturing the display device according to the fourth embodiment of the present disclosure includes substantially the same steps as those of the second embodiment, except for forming the dam structure and forming the adhesive layer. The same parts as those of the second embodiment are designated by the same or similar reference signs, and explanation for the same parts can be shortened or omitted.

In FIG. 11A, the dam structure 470 can be formed in the first pixel region P1 over the substrate 110 provided with the reflection electrode 132 by applying an organic insulating material and patterning it through a photolithography process. The dam structure 470 can have a hydrophobic property, and no dam structure can be provided in the second pixel region P2.

Then, an adhesive material layer 417a and 417b can be formed over the substrate 110 provided with the dam structure 470 by applying an adhesive material. The adhesive material can be applied substantially all over the entire surface of the substrate 110 by a slit coating or spin coating method.

In this situation, since the dam structure 470 of the first pixel region P1 has a hydrophobic property, the adhesive material layer 417a and 417b may not be formed on the dam structure 470. For example, the hydrophobic property can repel the adhesive material layer and prevent it from sticking to an upper surface of the dam structure 470. In addition, the adhesive material layer 417a formed in the recessed portion 116a surrounded by the dam structure 470 can have a higher height than the adhesive material layer 417b formed in other areas.

Next, in FIG. 11B, a stamp 280 provided with light-emitting elements 140 can be disposed over the substrate 110 provided with the adhesive material layer 417a and 417b, and the stamp 280 and the substrate 110 can be attached together such that the light-emitting element 140 can be in contact with the adhesive material layer 417a.

In this situation, the light-emitting element 140 corresponding to the first pixel region P1 can be in contact with the adhesive material layer 417a formed in the recessed portion 116a of the first pixel region P1, and the light-emitting element 140 corresponding to the second pixel region P2 may not be in contact with the adhesive material layer 417b formed in the recessed portion 116a of the second pixel region P2.

Next, in FIG. 11C, the adhesive material layer 417a and 417b can be cured, thereby forming the adhesive layer 417 and fixing the light-emitting element 140 on the substrate 110. Then, the stamp 280 can be detached from the substrate 110, so that the light-emitting element 140 can be transferred onto the adhesive layer 417 of the first pixel region P1 and no light-emitting element can be transferred onto the adhesive layer 417 of the second pixel region P2.

Next, in FIG. 11D, the second planarization layer 118 can be formed over the substrate 110 on which the light-emitting element 140 is transferred by applying an organic insulating material, and can be patterned through a photolithography process, thereby selectively exposing a top surface of the adhesive layer 417 corresponding to the reflection electrode 132 and the first connection electrode 134. Then, the second planarization layer 118 can be partially removed from its top surface through an ashing process to expose the protection layer 144 on the first and second element electrodes 141 and 142 of the light-emitting element 140.

Next, in FIG. 11E, the protection layer 144 of the light-emitting element 140 can be selectively removed through a dry etching process, thereby exposing the first and second element electrodes 141 and 142 of the light-emitting element 140.

Next, in FIG. 11F, the exposed adhesive layer 417 can be selectively removed through a photolithography process, thereby exposing top surfaces of the reflection electrode 132 and the first connection electrode 134.

Next, in FIG. 11G, the first electrode 252 and the second connection electrode 154 can be formed in each of the first and second pixel regions P1 and P2 by depositing a conductive material on the light-emitting element 140 and the second planarization layer 118 and patterning it through a photolithography process.

Here, as shown in FIG. 6, the first electrode 252a of the first pixel region P1 can have the opening 252H corresponding to the second element electrode 142, and as shown in FIG. 7, the first electrode 252b of the second pixel region P2 may not have an opening. For example, the second pixel region P2 can correspond to an empty pixel region or a dummy pixel.

Next, in FIG. 11H, the third planarization layer 119 can be formed on the first electrode 252 and the second connection electrode 154 by applying an organic insulating material and can be patterned through a photolithography process, thereby exposing the first electrode 252 and the second connection electrode 154.

Then, the third planarization layer 119 can be partially removed from its top surface through an ashing process, thereby exposing the second element electrode 142 of the light-emitting element 140.

Next, in FIG. 11I, the second electrode 162 can be formed on the third planarization layer 119 in each of the first and second pixel regions P1 and P2 by depositing a conductive material and then patterning it through a photolithography process.

In the first pixel region P1, the second electrode 162 can be in contact with the exposed second element electrode 142 of the light-emitting element 140 and can overlap with the first electrode 252a having the opening 252H.

On the other hand, in the second pixel region P2, the second electrode 162 can overlap with the first electrode 252b without an opening.

As such, in the method of manufacturing the display device according to the fourth embodiment of the present disclosure, by forming the dam structure 470 corresponding to the recessed portion 116a only in the first pixel region P1 and forming the adhesive layer 417 by a slit coating or spin coating method, only the light-emitting element 140 corresponding to the first pixel region P1 can be transferred from the stamp 280 to the substrate 110 while no light-emitting element is transferred to the second pixel region P2, so that a low resolution or low PPI display device can be manufactured.

In the display device of the present disclosure, by selectively providing the adhesive layer in the recessed portion of the planarization layer and transferring the light-emitting element onto the adhesive layer, it is possible to implement display devices of different resolutions and/or sizes using the same display panel.

In addition, by further providing the same structure of the hydrophobic property corresponding to the recessed portion, the adhesive layer can be easily and securely formed in a desired area, and a variety of coating methods can be applied.

Accordingly, the manufacturing processes of the display device can be optimized and the production energy can be reduced.

According to an embodiment, a display device and method of producing the same can significantly improve manufacturing flexibility and cost efficiency. For example, by utilizing a single, universal panel design, a diverse range of display devices can be produced with different resolutions, pixel pitches and screen sizes without needing to create unique production lines or tooling for each specific product. This method and configuration can reduce development costs and accelerate the time to market for new and diverse products. Further, this approach can allow for a more agile and economical manufacturing process that enables a swift response to the varied demands of consumers.

It will be apparent to those skilled in the art that various modifications and variations can be made in the electroluminescent display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate including a first pixel region and a second pixel region;
a planarization layer disposed on the substrate, the planarization layer including a recessed portion in each of the first pixel region and the second pixel region;
a first electrode disposed in each of the first pixel region and the second pixel region, the first electrode overlapping with the recessed portion;
a second electrode disposed in each of the first pixel region and the second pixel region, the second electrode overlapping with the first electrode; and
a light-emitting element disposed in the first pixel region, the light-emitting element being electrically connected to the first electrode and the second electrode of the first pixel region,
wherein no light-emitting element is included in the second pixel region.

2. The display device of claim 1, wherein the first electrode of the first pixel region has an opening, and the first electrode of the second pixel region has a solid and continuous surface that is free of any opening.

3. The display device of claim 2, wherein the light-emitting element includes a first element electrode and a second element electrode,
wherein the first element electrode is in contact with the first electrode of the first pixel region, and
wherein the second element electrode is spaced apart from the first electrode of the first pixel region, and the second element electrode is disposed in the opening in the first electrode of the first pixel region.

4. The display device of claim 1, further comprising an adhesive layer disposed in the recessed portion of the first pixel region.

5. The display device of claim 4, further comprising a dam structure disposed between the planarization layer and the first electrode in the first pixel region,
wherein the dam structure surrounds the recessed portion of the first pixel region.

6. The display device of claim 5, wherein the dam structure has a hydrophobic property.

7. The display device of claim 5, wherein the dam structure is only in the first pixel region and the second pixel region is free of any dam structure.

8. The display device of claim 7, wherein the adhesive layer is further disposed in the recessed portion of the second pixel region.

9. The display device of claim 1, further comprising a reflection electrode corresponding to the recessed portion in each of the first pixel region and the second pixel regions,
wherein the reflection electrode is disposed between the planarization layer and the first electrode.

10. The display device of claim 9, wherein the reflection electrode in the first pixel region is disposed between the planarization layer and the light-emitting element.

11. A display device, comprising:
a substrate including a first pixel region and a second pixel region;
a planarization layer disposed on the substrate, the planarization layer including recessed portion in each of the first pixel region and the second pixel region;
a first electrode disposed in each of the first pixel region and the second pixel region, the first electrode overlapping with the recessed portion;
a second electrode disposed in each of the first pixel region and the second pixel regions, the second electrode overlapping with the first electrode; and
a light-emitting element disposed in the first pixel region, the light-emitting element being electrically connected to the first electrode of the first pixel region and the second electrode of the first pixel region,
wherein the first electrode of the first pixel region has an opening, and the first electrode of the second pixel region does not have an opening.

12. The display device of claim 11, wherein the light-emitting element includes a first element electrode and a second element electrode,
wherein the first element electrode is in contact with the first electrode of the first pixel region, and
wherein the second element electrode is spaced apart from the first electrode of the first pixel region and the second element electrode is disposed in the opening in the first electrode of the first pixel region.

13. The display device of claim 11, further comprising an adhesive layer disposed in the recessed portion of the first pixel region.

14. The display device of claim 13, further comprising a dam structure disposed between the planarization layer and the first electrode in the first pixel region,
wherein the dam structure surrounds the recessed portion of the first pixel region.

15. The display device of claim 13, wherein the adhesive layer is further disposed in the recessed portion of the second pixel region.

16. The display device of claim 11, further comprising a reflection electrode corresponding to the recessed portion in each of the first pixel region and the second pixel region,
wherein the reflection electrode is disposed between the planarization layer and the first electrode.

17. A display device, comprising:
a substrate including an array of pixel regions, the array of pixel regions including at least one active pixel region and at least one inactive pixel region;
a planarization layer disposed on the substrate, the planarization layer including a plurality of recessed portions corresponding to the array of pixel regions, respectively;
a first electrode disposed in each of the at least one active pixel region and the at least one inactive pixel region;
a second electrode disposed in each of the at least one active pixel region and the at least one inactive pixel region, the second electrode overlapping with the first electrode; and
a light-emitting element disposed in the at least one active pixel region,
wherein the at least one inactive pixel region is free of any light-emitting element.

18. The display device of claim 17, wherein the first electrode of the at least one active pixel region includes an opening, and
wherein the first electrode of the at least one inactive pixel region includes a continuous surface lacking any opening.

19. The display device of claim 17, wherein the at least one active pixel region includes a plurality of active pixel regions, and the at least one inactive pixel region includes a plurality of inactive pixel regions, and
wherein a ratio of the plurality of active pixel regions to the plurality of inactive pixel regions in the array of pixel regions is 1 to N, where N is a positive integer greater than 1.
